(19) United States
(12) Patent Application Publication
(10) Pub. No.: US 2025/0193999 A1
(43) Pub. Date: Jun. 12, 2025

(54) PRINTED CIRCUIT BOARD

(71) Applicant: Robert Bosch GmbH, Stuttgart (DE)

(72) Inventors: Guenter Gera, Leonberg (DE); Felix Egbert, Neustadt An Der Weinstrasse (DE); Nils Draese, Rutesheim (DE)

(21) Appl. No.: 18/916,778

(22) Filed: Oct. 16, 2024

(30) Foreign Application Priority Data
Dec. 7, 2023 (DE) 10 2023 212 333.9

(51) Int. Cl. H05K 1/02; H02H 7/08

(52) U.S. Cl. CPC H05K 1/0254; H02H 7/08

(57) ABSTRACT

A printed circuit board in which a braking resistor is implemented that is designed as a clamping path. The clamping path is formed by at least two conductive layers within the printed circuit board that run at a distance from one another and allow a current to flow back and forth.

### CROSS REFERENCE

The present application claims the benefit under 35 U.S.C. § 119 of German Patent No. DE 10 2023 212 333.9 filed on Dec. 7, 2023, which is expressly incorporated herein by reference in its entirety.

### FIELD

The present invention relates to a printed circuit board having a braking resistor and an intelligent current distributor having such a printed circuit board. The present invention further relates to a method that is carried out using such a printed circuit board.

### BACKGROUND INFORMATION

A printed circuit board (PCB) is used as a carrier for electronic components and allows for mechanical fastening and electrical connection of these components. Printed circuit boards are used in various electrical and electronic devices, such as intelligent current distributors, also known as Powernet Guardians (PNG). A PNG offers a holistic concept for on-board electrical systems, in particular in motor vehicles. In motor vehicles, the PNG ensures that power is supplied to safety-relevant consumers at all times. An electronic disconnecting switch can be used for this purpose, which disconnects the safety on-board electrical system from the rest of the on-board electrical system in the event of a fault.

A braking resistor is always installed when a current is to be limited. For example, it is known that the run-down times of an electric motor can be reduced by using a brake circuit that has such a braking resistor. This is achieved by short-circuiting the generator voltage of the electric motor via a load resistor when it runs down, thereby generating an electromagnetic braking torque. In particular when high currents are to be switched on and off, it is necessary to provide a braking path, for example a clamping path, that can convert the energy of the electromagnetic fields into thermal energy.

The function of a braking resistor is carried out as follows:

During pre-charging, the electrical capacity of the on-board electrical system is charged. To limit the current during charging, a pre-charge path having a resistance of about 55 mΩ is required.

During the disconnection of a channel, the magnetic energy must be consumed or burned. To reduce the load on the clamping diodes, a resistance path of 55 mΩ can be used.

Both functions are realized using the same resistance path. The pre-charge/clamping path is typically realized by means of SMD resistors.

The resistance of a conductor track can be calculated using

$$R = {ρ}_{20 ° C .} \frac{l}{w \cdot {h}_{Trace}} ( 1 + α \cdot Δ T ) , \\ where {ρ}_{20 ° C .} = 17.2 μΩ mm and α = 0.0039 \frac{1}{K} .$$

h is the thickness of the conductor track, typically 30 μm or 70 μm.

The conductor track resistance can be set to a specific value.

The inductance of a two-wire PCB track can be calculated using

$$L = {μ}_{0} {μ}_{R} \frac{l}{2} \frac{h}{w} , where {μ}_{0} = \frac{4 π}{10} \frac{nH}{mm} and {μ}_{R} = 1.$$

h is the thickness of the woven fabric between the two conductor tracks, typically 130 to 150 μm.

Because both functions, clamping and pre-charging, are in the same temporal range of a few milliseconds, the thermal capacitance mainly defines the performance of the resistor.

The thermal capacitance can be calculated as follows:

$${C}_{Th} = {c}_{Th} \cdot p \cdot l \cdot w \cdot h , where {c}_{Th} = 0.385 \frac{J}{K kg} and p = 8.89 \frac{mg}{{mm}^{3}} .$$

When, for example, high currents are to be switched on or off by means of MOSFETs, it is necessary to provide a clamping path that can convert the energy of the electromagnetic fields into thermal energy.

A so-called clamping path can be used as a braking resistor, for example. For example, it is conventional to realize the clamping using suppressor diodes or measuring resistors or shunts that provide sufficient thermal mass.

The clamping path must present a defined electrical resistance, have sufficient thermal mass to absorb the energy, and have as low an inductance as possible to avoid time delays.

It is conventional to implement a clamping resistor on an outer layer of a printed circuit board. A value of electrical resistance is set via the length L and width B of the conductor track. Furthermore, the thermal capacitance of the clamping path can be adjusted at a constant L/B ratio without affecting the electrical resistance. However, this approach produces a relatively high inductance. This results in a high induced voltage U=L*di/dt, in particular if the current in the clamping path is to increase in a very short time, which counteracts the current flow through the clamping path.

A solution with significantly lower inductance is therefore sought in order to exploit the full potential of the PCB clamping path.

### SUMMARY

The present invention provides a printed circuit board, an intelligent current distributor, and a method. Example embodiments can be found in the disclosure herein.

According to an example embodiment of the present invention, a printed circuit board is provided in which a braking resistor is implemented that is designed as a clamping path, wherein the clamping path is formed by at least two conductive layers within the printed circuit board that run at a particularly small distance from one another and allow a current to flow back and forth. This allows a closed conductor loop to be formed for the current.

This provides a particularly low-inductance clamping path within the printed circuit boards, in which the current flows back and forth between the two layers of a core, for example. The small distance between the printed circuit board layers results in very low inductance. The inductance can be further reduced by an additional meander-shaped arrangement within the two layers. The connection between the layers can be realized via through-platings.

According to an example embodiment of the present invention, the clamping path can also be distributed over a plurality of cores, as long as the forward and return lines on the two layers of the core are always located one above the other.

The design on the inner layers has the particular advantage that a particularly small copper thickness tolerance can be achieved.

In addition, according to an example embodiment of the present invention, the printed circuit board-based clamping path can be designed to be self-braking; the resistance increases during the clamping process. The thermal capacitance of the clamping path can be adjusted at a constant L/B ratio without affecting the electrical resistance or inductance. Furthermore, the temperature increase of the clamping path can be adjusted via the thermal capacitance for known load cases.

Due to the high temperature coefficient of copper, the following should be noted:

At the beginning of the clamping process, the clamping path is cold and is therefore low-resistance. Therefore, the switches are very well relieved. At the end of the clamping process, the clamping path is warm and therefore high-resistance. Therefore, less energy remains for the suppressor diodes.

For example, with a temperature increase of 40 K, the resistance increases by 15%.

The presented intelligent current distributor, also referred to as Powernet Guardian (PNG), has at least one printed circuit board of the type described herein.

This intelligent current distributor is designed, for example, to disconnect a channel having safety-relevant consumers from another channel in an on-board electrical system, wherein the clamping path in the printed circuit board is designed to convert electrical energy fed in as a result of the disconnection into thermal energy.

The method described according to an example embodiment of the present invention is used to convert electrical energy to thermal energy using a printed circuit board of the type described herein. The method is used, for example, to convert electrical energy fed in by switching currents using MOSFETS into thermal energy or to reduce the run-down times of an electric motor. In particular, the process is carried out using an intelligent current distributor.

Further advantages and embodiments of the present invention can be found in the description and the attached drawings.

Of course, the features mentioned above and those still to be explained below can be used not only in the respectively specified combinations, but also in other combinations or alone, without departing from the scope of the present invention.

### BRIEF DESCRIPTION OF THE DRAWINGS

FIG. 1 is a schematic representation of a clamping path around a printed circuit board core, according to an example embodiment of the present invention.

FIG. 2 shows a possible application of a printed circuit board having a clamping path, according to an example embodiment of the present invention.

### DETAILED DESCRIPTION OF EXAMPLE EMBODIMENTS

The present invention is shown schematically in the figures on the basis of embodiments and is described in detail below with reference to the figures.

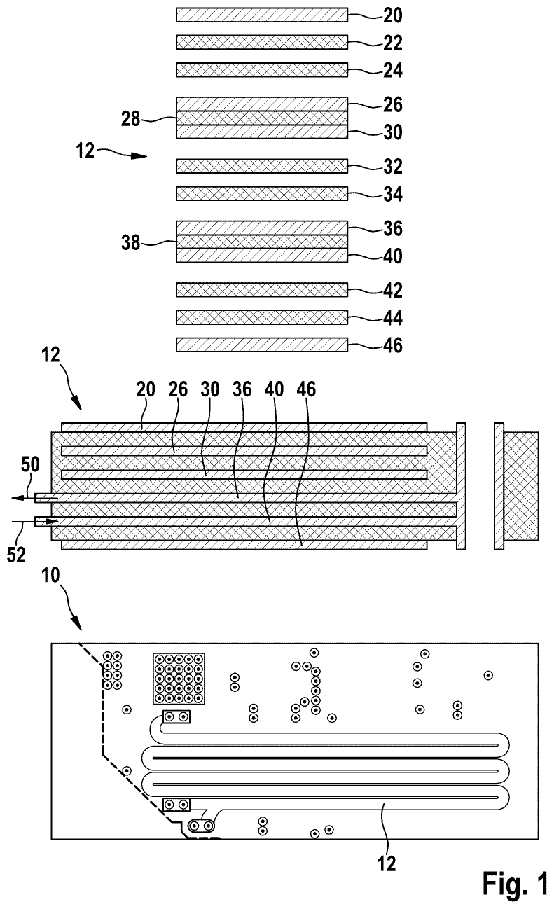

FIG. 1 is a schematic representation of a printed circuit board 10 in which a clamping path 12 is integrated that in turn implements a braking resistor. This clamping path 12 is a low-inductance clamping path and is integrated in the printed circuit board 10. This printed circuit board 10 has a thickness of approximately 1.6 mm.

The representation above shows possible layers of the clamping path 12. This clamping path comprises a first copper layer 20, a first woven fabric layer 22, a second woven fabric layer 24, a second copper layer 26, a third woven fabric layer 28, a third copper layer 30, a fourth woven fabric layer 32, a fifth woven fabric layer 34, a fourth copper layer 36, a sixth woven fabric layer 38, a fifth copper layer 40, a seventh woven fabric layer 42, an eighth woven fabric layer 44 and a sixth copper layer 46. The copper layers 20, 26, 30, 36, 40, 46 each have a thickness of, for example, 35 μm.

Because the current flows back and forth across the two layers of a core, a particularly low-inductance clamping path is realized. The small distance between the copper layers also results in very low inductance. An additional meander-shaped arrangement of the copper layers further supports this.

The clamping path can also be distributed over a plurality of cores, as long as the forward and return lines, as shown by arrows 50 and 52, are always located one above the other on the two layers of the core.

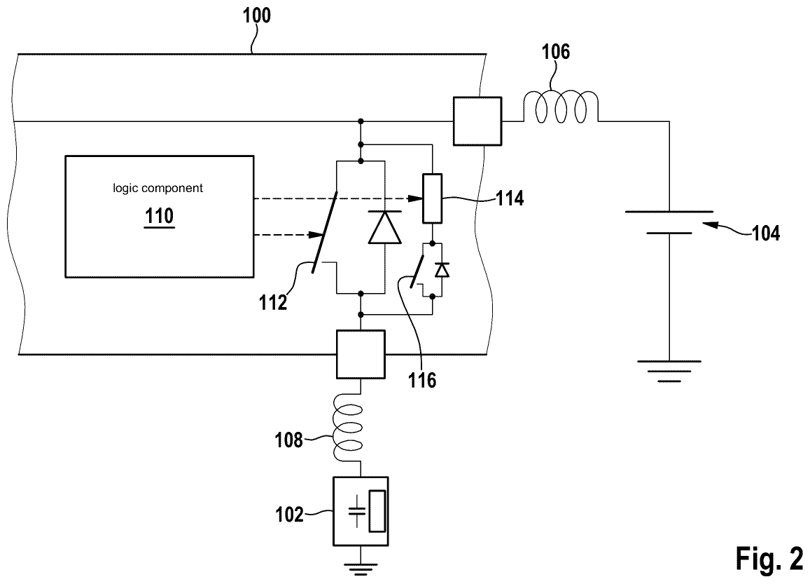

FIG. 2 shows a possible realization of the presented printed circuit board in an intelligent current distributor, known as a Powernet Guardian (PNG). The representation shows a printed circuit board 100 which is connected to a load 102 and a battery 104. Furthermore, a first inductor 106 and a second inductor 108 are shown in the connected circuit.

A logic component 110, a first switching element 112 and a braking resistor 114, to which a second switching element 116 is assigned, are provided in the printed circuit board 100. When the first switching element 112 is opened, the second switching element 116 is closed, so that the energy fed to the circuit primarily by the two inductors 106, 108 can be converted to heat in the braking resistor 114. The first switching element 112 is thus the electronic disconnecting switch as explained above.

The two switching elements 112, 116 are thus typically alternately opened and closed.

What is claimed is:

1. A printed circuit board in which a braking resistor is implemented that is configured as a clamping path, wherein the clamping path is formed by at least two conductive layers within the printed circuit board that run at a distance from one another and allow a current to flow back and forth.

2. The printed circuit board according to claim 1, wherein the clamping path is formed by two layers of a core of the printed circuit board.

3. The printed circuit board according to claim 1, wherein the clamping path is distributed over a plurality of cores of the printed circuit board.

4. The printed circuit board according to claim 1, wherein a layer including a woven fabric is arranged at least in portions between the at least two layers.

5. The printed circuit board according to claim 1, wherein a meander-shaped arrangement of the copper structure is provided on the two layers of one or more cores of the printed circuit board.

6. An intelligent current distributor, comprising:
at least one printed circuit board in which a braking resistor is implemented that is configured as a clamping path, wherein the clamping path is formed by at least two conductive layers within the printed circuit board that run at a distance from one another and allow a current to flow back and forth.

7. The intelligent current distributor according to claim 6, wherein the intelligent current distributor is configured to disconnect a channel having consumers from another channel in an on-board electrical system, wherein the clamping path in the printed circuit board is configured to convert electrical energy fed in as a result of the disconnection into thermal energy.

8. A method, comprising:
converting electrical energy into thermal energy using a printed circuit board, wherein, in the printed circuit board, a braking resistor is implemented that is configured as a clamping path, wherein the clamping path is formed by at least two conductive layers within the printed circuit board that run at a distance from one another and allow a current to flow back and forth.

9. The method according to claim 8, wherein the converting of the electrical energy includes converting electrical energy fed in by switching currents using MOSFETs into thermal energy.

10. The method according to claim 8, wherein the converting of the electrical energy into therman energy reduces run-down times of an electric motor.

11. The method according to claim 8, wherein the method is carried out using an intelligent current distributor.
